(19) United States
(12) Patent Application Publication
(10) Pub. No.: US 2026/0075705 A1
(43) Pub. Date: Mar. 12, 2026

(54) MOTHER BOARD FOR DISPLAY DEVICE AND DISPLAY DEVICE

(71) Applicant: Magnolia White Corporation, Tokyo (JP)

(72) Inventors: Hideyuki TAKAHASHI, Tokyo (JP); Sho YANAGISAWA, Tokyo (JP)

(73) Assignee: Magnolia White Corporation, Tokyo (JP)

(21) Appl. No.: 19/324,254

(22) Filed: Sep. 10, 2025

(30) Foreign Application Priority Data
Sep. 11, 2024 (JP) 2024-157569

(51) Int. Cl. H05K 1/02

(52) U.S. Cl. CPC H05K 1/0268; H05K 2201/10128

(57) ABSTRACT

According to one embodiment, a mother board for a display device includes a rib layer having pixel apertures, and inspection pads disposed in a peripheral area. The inspection pads each have a first metal layer and a second metal layer. The rib layer has a first aperture where the second metal layer is in contact with the first metal layer. The first metal layer includes a first layer, a second layer overlapping the first layer, and a third layer overlapping the second layer. The third layer has an area exposing the second layer in the first aperture. The second metal layer has a first contact portion in contact with the second layer and a second contact portion in contact with the third layer in the area.

### CROSS-REFERENCE TO RELATED APPLICATION

This application is based upon and claims the benefit of priority from Japanese Patent Application No. 2024-157569, filed Sep. 11, 2024, the entire contents of which are incorporated herein by reference.

### FIELD

Embodiments described herein relate generally to a mother board for a display device, and a display device.

### BACKGROUND

In recent years, display devices in which organic light-emitting diodes (OLEDs) are applied as display elements have been put into practical use. In display devices of this type, a technology of suppressing degradation in reliability is required.

### BRIEF DESCRIPTION OF THE DRAWINGS

FIG. 1 is a plan view schematically showing a configuration example of a display device according to the first embodiment.

FIG. 2 is a plan view schematically showing an example of layout of subpixels.

FIG. 3 is a cross-sectional view schematically showing the display device taken along the line III-III in FIG. 2.

FIG. 4 is a plan view schematically showing a mother board according to the first embodiment.

FIG. 5 is a plan view schematically showing a part of the mother board.

FIG. 6 is a cross-sectional view schematically showing the display device taken along the line VI-VI in FIG. 5.

FIG. 7 is a partially enlarged view showing a VII portion in FIG. 6.

FIG. 8 is a partially enlarged view showing a VIII portion in FIG. 6.

FIG. 9 is a flowchart showing an example of a method of manufacturing the display device.

FIG. 10A is a cross-sectional view schematically showing a processing step in the manufacturing of the display device.

FIG. 10B is a cross-sectional view schematically showing another processing step in the manufacturing of the display device.

FIG. 11A is a cross-sectional view schematically showing still another processing step in the manufacturing of the display device.

FIG. 11B is a cross-sectional view schematically showing still another processing step in the manufacturing of the display device.

FIG. 12A is a cross-sectional view schematically showing still another processing step in the manufacturing of the display device.

FIG. 12B is a cross-sectional view schematically showing still another processing step in the manufacturing of the display device.

FIG. 13A is a cross-sectional view schematically showing still another processing step in the manufacturing of the display device.

FIG. 13B is a cross-sectional view schematically showing still another processing step in the manufacturing of the display device.

FIG. 14A is a cross-sectional view schematically showing still another processing step in the manufacturing of the display device.

FIG. 14B is a cross-sectional view schematically showing still another processing step in the manufacturing of the display device.

FIG. 15A is a cross-sectional view schematically showing still another processing step in the manufacturing of the display device.

FIG. 15B is a cross-sectional view schematically showing still another processing step in the manufacturing of the display device.

FIG. 16A is a cross-sectional view schematically showing still another processing step in the manufacturing of the display device.

FIG. 16B is a cross-sectional view schematically showing still another processing step in the manufacturing of the display device.

FIG. 17A is a cross-sectional view schematically showing still another processing step in the manufacturing of the display device.

FIG. 17B is a cross-sectional view schematically showing still another processing step in the manufacturing of the display device.

FIG. 18A is a cross-sectional view schematically showing still another processing step in the manufacturing of the display device.

FIG. 18B is a cross-sectional view schematically showing still another processing step in the manufacturing of the display device.

FIG. 19A is a cross-sectional view schematically showing still another processing step in the manufacturing of the display device.

FIG. 19B is a cross-sectional view schematically showing still another processing step in the manufacturing of the display device.

FIG. 20A is a cross-sectional view schematically showing still another processing step in the manufacturing of the display device.

FIG. 20B is a cross-sectional view schematically showing still another processing step in the manufacturing of the display device.

FIG. 21 is a cross-sectional view schematically showing a step of forming a display element.

FIG. 22 is a cross-sectional view schematically showing another step of forming the display element.

FIG. 23 is a cross-sectional view schematically showing still another step of forming the display element.

FIG. 24 is a cross-sectional view schematically showing still another step of forming the display element.

FIG. 25 is a diagram illustrating an aperture overlapping an inspection pad.

FIG. 26 is a cross-sectional view schematically showing a processing step in the manufacturing of a display device according to a comparative example.

FIG. 27 is a cross-sectional view schematically showing another processing step in the manufacturing of the display device according to a comparative example.

FIG. 28 is a cross-sectional view schematically showing still another processing step in the manufacturing of a display device according to a comparative example.

FIG. 29 is a cross-sectional view schematically showing still another processing step in the manufacturing of a display device according to a comparative example.

FIG. 30 is a cross-sectional view schematically showing still another processing step in the manufacturing of a display device according to a comparative example.

FIG. 31 is a plan view schematically showing a mother board according to the second embodiment.

### DETAILED DESCRIPTION

In general, according to one embodiment, a mother board for a display device, comprises a plurality of panel portions each including a display area and a peripheral area surrounding the display area, display elements disposed in the display area, a rib layer disposed in the display area and the peripheral area and having pixel apertures overlapping the display elements, and inspection pads disposed in the peripheral area. The inspection pads include a first metal layer and a second metal layer overlapping the first metal layer. The rib layer is disposed between the first metal layer and the second metal layer and further has a first aperture where the second metal layer is in contact with the first metal layer. The first metal layer includes a first layer formed of a first metal material, a second layer formed of a second metal material and overlapping the first layer, and a third layer formed of the first metal material and overlapping the second layer. The third layer has an area exposing the second layer in the first aperture. The second metal layer has a first contact portion in contact with the second layer and a second contact portion in contact with the third layer in the area.

According to another embodiment, a mother board for a display device comprises a plurality of panel portions each having a display area and a peripheral area surrounding the display area, display elements arranged in the display area, a rib layer arranged in the display area and the peripheral area and having pixel apertures overlapping the display elements, and inspection pads arranged in the peripheral area. The inspection pads each include a first metal layer and a second metal layer overlapping the first metal layer. The rib layer is disposed between the first metal layer and the second metal layer and has a first aperture where the second metal layer is brought into contact with the first metal layer. The first metal layer comprises a first layer formed of a first metal material, a second layer formed of a second metal material and overlapping the first layer, and a third layer formed of the first metal material and overlapping the second layer. The second metal layer comprises a fourth layer formed of the first metal material, a fifth layer formed of the second metal material and overlapping the fourth layer, and a sixth layer formed of the first metal material and overlapping the fifth layer. The inspection pads each have a first portion in which the first layer, the second layer, the fourth layer, the fifth layer, and the sixth layer are stacked, and a second portion in which the first layer, the second layer, the third layer, the fourth layer, the fifth layer, and the sixth layer are stacked.

According to still another embodiment, a display device comprises a display area, a peripheral area surrounding the display area, display elements arranged in the display area, a rib layer arranged in the display area and the peripheral area and having pixel apertures overlapping the display elements, and inspection pads disposed in the peripheral area. The inspection pads each include a first metal layer and a second metal layer overlapping the first metal layer. The rib layer is disposed between the first metal layer and the second metal layer and has a first aperture where the second metal layer is brought into contact with the first metal layer. The first metal layer comprises a first layer formed of a first metal material, a second layer formed of a second metal material and overlapping the first layer, and a third layer formed of the first metal material and overlapping the second layer. The third layer has an area exposing the second layer in the first aperture. The second metal layer has a first contact portion in contact with the second layer in the area and a second contact portion in contact with the third layer.

With configurations such as described above, it is possible to provide a mother board for display device which can suppress the decrease in reliability, such a display device.

An embodiment will now be described hereinafter with reference to the accompanying drawings. Note that the disclosure is merely an example, and proper changes within the spirit of the invention, which are easily conceivable by a skilled person, are included in the scope of the invention as a matter of course.

In addition, as to the drawings, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as a first direction X, a direction along the Y axis is referred to as a second direction Y and a direction along the Z axis is referred to as a third direction Z. Further, viewing the constitutional elements parallel to the Z direction is referred to as plan view.

In the following description, the expression “overlapping” refers not only to cases where other elements overlap the target element from the third direction Z, but also to cases where other elements overlap the target element from the direction opposite to the third direction Z. Further, the expression “overlapping” refers not only to cases where the target elements are in direct contact with each other, but also to cases where the target elements are spaced apart or where other elements are located between the target elements.

The display device according to one embodiment is an organic electroluminescence display device comprising organic light-emitting diodes (OLEDs) as display elements, and may be incorporated into various electronic devices such as televisions, personal computers, in-vehicle devices, tablet terminals, smartphones, mobile phone terminals, and wearable devices.

### First Embodiment

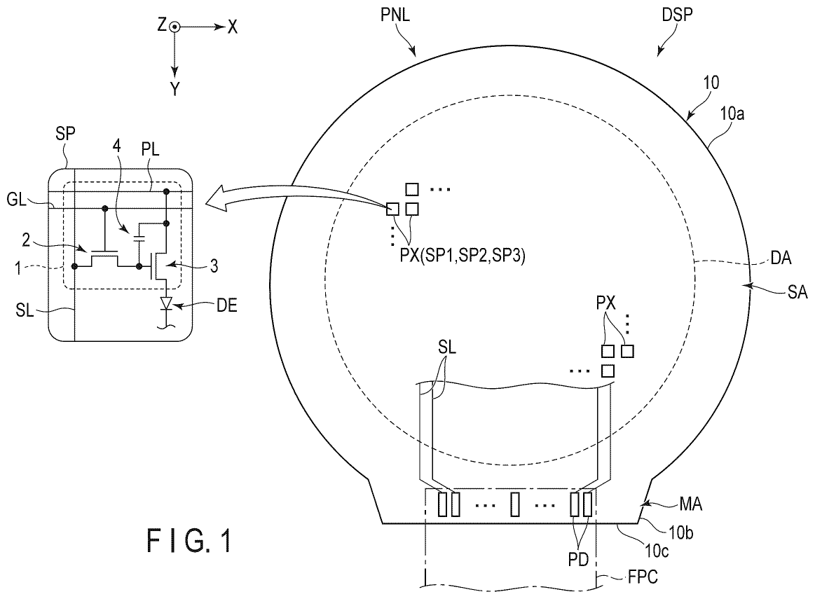

FIG. 1 is a plan view schematically showing a configuration example of a display device DSP according to this embodiment. The display device DSP comprises a display panel PNL including an insulating substrate 10 and a plurality of conductive pads PD. The substrate 10 includes a circular main body portion 10a and an extending portion 10b extending from the main body portion 10a in a second direction Y. The extending portion 10b is formed into a trapezoidal shape such that the width along the first direction X decreases as the location is farther away from the main body portion 10a. The extending portion 10b has a substrate edge 10c extending along the first direction X.

Note that the shape of the substrate 10 in plan view may as well be some other shape such as rectangular, square, or elliptical. The substrate 10 is formed, for example, of an insulating material such as glass or plastic.

The display panel PNL further comprises a display area DA that displays images and a peripheral area SA that surrounds the display area DA. The display area DA overlaps the main body portion 10a in plan view. In this embodiment, the shape of the display area DA in plan view is circular. But, the shape of the display area DA in plan view may as well be some other shape such as rectangular, square, or elliptical.

The peripheral area SA has a mount area MA. The mount area MA corresponds to the region overlapping the extending portion 10b in plan view. The pads PD are provided in the mount area MA. In the example shown in FIG. 1, the pads PD are aligned at equal intervals along the first direction X. The flexible substrate FPC is connected to the pads PD via an adhesive. Not only the flexible substrate FPC, but also IC chips and the like may be further mounted in the mount area MA.

The display area DA includes a plurality of pixels PX arranged in a matrix along the first direction X and the second direction Y. Each of the pixels PX contains a plurality of subpixels SP. For example, each pixel PX includes a blue subpixel SP1, a green subpixel SP2, and a red subpixel SP3. Note that the pixels PX may contain four or more subpixels with an addition of subpixels of some other color such as white, in addition to the above-listed three-color subpixels.

The subpixels SP each comprise a pixel circuit 1 and a display element DE driven by the pixel circuit 1. The pixel circuit 1 comprise a pixel switch 2, a drive transistor 3, and a capacitor 4. The pixel switch 2 and the drive transistor 3 are switching elements constituted, for example, by thin-film transistors.

In the pixel switch 2, the gate electrode is connected to a respective scanning line GL. One of the source electrode and drain electrode of the pixel switch 2 is connected to a respective signal line SL, and the other is connected to the gate electrode of the drive transistor 3 and the capacitor 4. In the example shown in FIG. 1, the scanning line GL extends along the first direction X, and the signal line SL extends along the second direction Y. The signal line SL connects the pixel circuit 1 and the respective pad PD to each other. In the drive transistor 3, one of the source electrode and drain electrode is connected to a power supply line PL and the capacitor 4, and the other is connected to the anode of the display element DE. Note that the configuration of the pixel circuit 1 is not limited to that of the example shown.

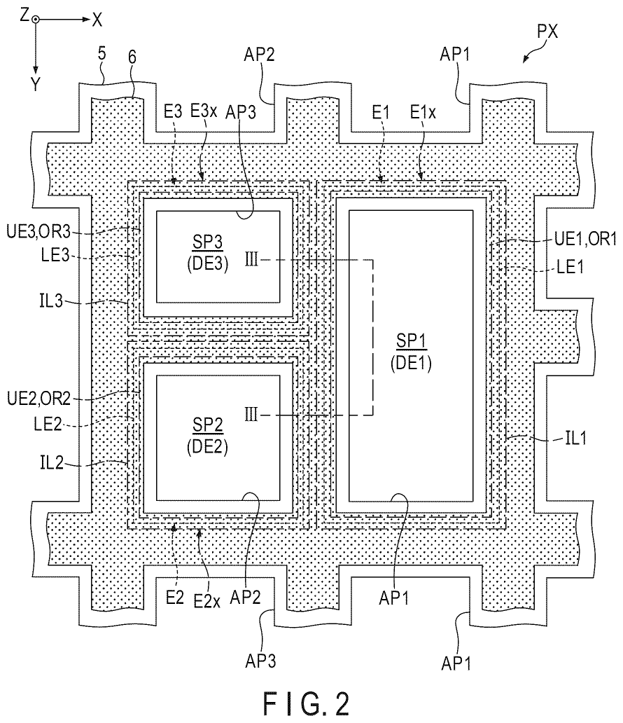

FIG. 2 is a plan view schematically showing an example of the layout of the subpixels SP1, SP2, and SP3. In the example shown in FIG. 2, the subpixels SP2 and SP3 are arranged along the subpixel SP1 in the first direction X. Further, the subpixels SP2 and SP3 are arranged along the second direction Y.

When the subpixels SP1, SP2, and SP3 are arranged in such a layout, a column in which the subpixels SP2 and SP3 are alternately arranged along the second direction Y, and a column in which multiple subpixels SP1 are repeatedly arranged along the second direction Y are formed in the display area DA. These columns are arranged alternately along the first direction X. Note that the layout of the subpixels SP1, SP2, and SP3 is not limited to that of the example shown in FIG. 2.

In the display area DA, a rib layer 5 is disposed. The rib layer 5 has pixel apertures AP1, AP2, and AP3 in the subpixels SP1, SP2, and SP3, respectively. In the example shown in FIG. 2, the pixel aperture AP1 is larger than the pixel aperture AP2, and the pixel aperture AP2 is larger than the pixel aperture AP3.

That is, among the subpixels SP1, SP2, and SP3, the aperture ratio of the subpixel SP1 is the largest, and the aperture ratio of the subpixel SP3 is the smallest. Note that the sizes of the pixel apertures AP1, AP2, and AP3 are not limited to those of this example. For example, at least two of the pixel apertures AP1, AP2, and AP3 may have the same size.

The subpixel SP1 comprises a lower electrode LE1, an upper electrode UE1, and an organic layer OR1, each overlapping the pixel aperture AP1. The subpixel SP2 comprises a lower electrode LE2, an upper electrode UE2, and an organic layer OR2, each overlapping the pixel aperture AP2. The subpixel SP3 includes a lower electrode LE3, an upper electrode UE3, and an organic layer OR3, each overlapping the pixel aperture AP3.

In the display area DA, display elements DE1, DE2, and DE3 are disposed. The portions of the lower electrode LE1, upper electrode UE1, and organic layer OR1, which overlap the pixel aperture AP1 constitute a display element DE1 of the subpixel SP1. The portions of the lower electrode LE2, upper electrode UE2, and organic layer OR2, which overlap the pixel aperture AP2 constitute a display element DE2 of the subpixel SP2. The portions of the lower electrode LE3, upper electrode UE3, and organic layer OR3, which overlap the pixel aperture AP3 constitute a display element DE3 of the subpixel SP3. The display elements DE1, DE2, and DE3 may further include a cap layer, which will be described later. The rib layer 5 surrounds each of the display elements DE1, DE2, and DE3.

In the display area DA, a partition 6 is disposed. The partition 6 is located above the rib layer 5 and entirely overlaps the rib layer 5. In the example shown in FIG. 2, the partition 6 has a planar shape similar to that of the rib layer 5. That is, the partition 6 has apertures in locations corresponding to the subpixels SP1, SP2, and SP3, respectively.

From another perspective, the rib layer 5 and partition 6 have a grid pattern in plan view, enclosing each of the display elements DE1, DE2, and DE3. The partition 6 encloses the pixel apertures AP1, AP2, and AP3. The partition 6 serves as wiring for supplying a common voltage to the upper electrodes UE1, UE2, and UE3.

In this embodiment, below the lower electrodes LE1, LE2, and LE3, inorganic insulating layers IL1, IL2, and IL3 are disposed, respectively. In the example shown in FIG. 2, the inorganic insulating layers IL1, IL2, and IL3 are spaced apart from each other.

The inorganic insulating layers IL1, IL2, and IL3 each have an outer shape that is slightly larger than that of the lower electrodes LE1, LE2, and LE3. That is, an end portion E1x of the inorganic insulating layer IL1 protrudes from an end portion E1 of the lower electrode LE1 over the entire circumference.

Similarly, an end portion E2x of the inorganic insulating layer IL2 protrudes from an end portion E2 of the lower electrode LE2 over the entire circumference. An end portion E3x of the inorganic insulating layer IL3 protrudes from an end portion E3 of the lower electrode LE3 over the entire circumference.

Note that the shapes of the inorganic insulating layers IL1, IL2, and IL3 are not limited to those of the examples shown in FIG. 2. For example, parts of the inorganic insulating layers IL1, IL2, and IL3 may be connected. Or, parts of the end portions E1x, E2x, and E3x may overlap the lower electrodes LE1, LE2, and LE3, respectively.

The lower electrodes LE1, LE2, and LE3 are connected to the pixel circuits 1 (more specifically, the drain electrodes of the drive transistors 3 shown in FIG. 1) of the subpixels SP1, SP2, and SP3, respectively, through contact holes not shown. The contact holes not shown all overlap the rib layer 5 and the partition 6.

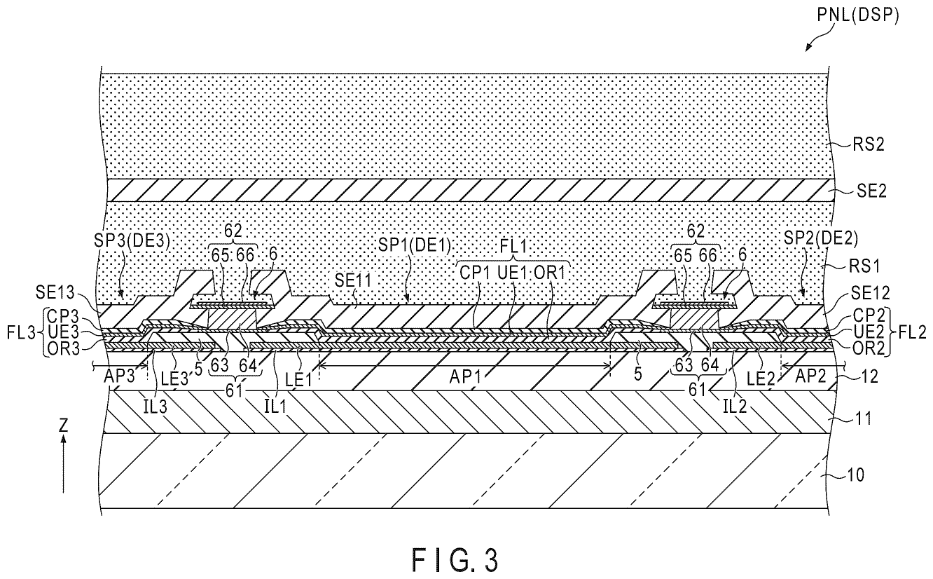

FIG. 3 is a cross-sectional view schematically showing the display device DSP taken along the line III-III in FIG. 2. The circuit layer 11 is disposed on the substrate 10 described above. The circuit layer 11 includes various circuits and wiring lines such as the pixel circuits 1, scanning lines GL, signal lines SL, and power supply lines PL shown in FIG. 1. The circuit layer 11 is covered by an organic insulating layer 12. The organic insulating layer 12 functions as a planarization film to planarize the unevenness caused by the circuit layer 11.

The inorganic insulating layers IL1, IL2, and IL3 are disposed on the organic insulating layer 12. The lower electrodes LE1, LE2, and LE3 are respectively disposed on the inorganic insulating layers IL1, IL2, and IL3. That is, the inorganic insulating layers IL1, IL2, and IL3 are disposed between the organic insulating layer 12 and the lower electrodes LE1, LE2, and LE3 in the display area DA.

The rib layer 5 is disposed on the organic insulating layer 12 and the lower electrodes LE1, LE2, and LE3. The end portions of the lower electrodes LE1, LE2, and LE3 (end portions E1, E2, and E3 shown in FIG. 2) and the end portions of the inorganic insulating layers IL1, IL2, and IL3 (end portions E1x, E2x, and E3x shown in FIG. 2) are all covered by the rib layer 5.

The partition 6 includes a conductive lower portion 61 disposed on the rib layer 5 and an upper portion 62 disposed on the lower portion 61. The upper portion 62 has a width greater than that of the lower portion 61. With this configuration, both end portions of the upper portion 62 protrude beyond the side surfaces of the lower portion 61. That is, the partition 6 has an overhanging shape in which both end portions of the upper portion 62 protrude beyond the side surfaces of the lower portion 61.

In the example shown in FIG. 3, the lower portion 61 has a bottom layer 63 and an axis layer 64. The bottom layer 63 is located between the axis layer 64 and the rib layer 5. Further, in the example shown in FIG. 3, the upper portion 62 has a first top layer 65 and a second top layer 66. The first top layer 65 is disposed on the axis layer 64. The second top layer 66 is disposed on the first top layer 65.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the lower portion 61 of the partition 6.

The display element DE1 includes a cap layer CP1 that covers the upper electrode UE1. The display element DE2 includes a cap layer CP2 that covers the upper electrode UE2. The display element DE3 includes a cap layer CP3 that covers the upper electrode UE3. The cap layers CP1, CP2, and CP3 serve as optical adjustment layers to improve the light extraction efficiency of the light emitted from the organic layers OR1, OR2, and OR3, respectively.

In the following description, the stacked layer body constituted by the organic layer OR1, the upper electrode UE1, and the cap layer CP1 is referred to as a stacked-layered film FL1, the stacked layer body constituted by the organic layer OR2, the upper electrode UE2, and the cap layer CP2 is referred to as a stacked-layered film FL2, and the stacked layer body constituted by the organic layer OR3, the upper electrode UE3, and the cap layer CP3 is referred to as a stacked-layered film FL3.

In the subpixels SP1, SP2, and SP3, sealing layers SE11, SE12, and SE13 are disposed to cover the stacked-layered films FL1, FL2, and FL3, respectively. Specifically, the sealing layer SE11 continuously covers the partition 6 surrounding the cap layer CP1 and the subpixels SP1. The sealing layer SE12 continuously covers the partition 6 surrounding the cap layer CP2 and the subpixels SP2. The sealing layer SE13 continuously covers the partition 6 surrounding the cap layer CP3 and the subpixels SP3.

In the example shown in FIG. 3, the sealing layer SE11 on the partition 6 between the subpixels SP1 and SP2 is spaced apart from the sealing layer SE12 on the partition 6. Further, the sealing layer SE11 on the partition 6 between the subpixels SP1 and SP3 is spaced apart from the sealing layer SE13 on the partition 6. Note here that any two of the sealing layers SE11, SE12, and SE13 may come into contact with each other above the partition 6.

For example, between the sealing layers SE11, SE12, and SE13 and the upper portion 62 of the partition 6, gaps are formed. At least portions of these gaps may be filled with the stacked-layered films FL1, FL2, and FL3, respectively.

The sealing layers SE11, SE12, and SE13 are covered by a resin layer RS1. The resin layer RS1 is covered by a sealing layer SE2. The sealing layer SE2 is covered by a resin layer RS2. The resin layers RS1, RS2, and the sealing layer SE2 are continuously provided over at least the entire display area DA and a portion thereof extends over to the peripheral area SA.

A cover member such as a polarizer, protective film, or cover glass may be further disposed above the resin layer RS2. Such a cover member may be adhered to the resin layer RS2 via an adhesive layer such as an optical clear adhesive (OCA). Further, above the display elements DE1, DE2, and DE3, color filters corresponding to the colors of the subpixels SP1, SP2, and SP3 may be provided, respectively.

The organic insulating layer 12 is formed from an organic insulating material such as polyimide. The inorganic insulating layers, IL1, IL2, and IL3, the rib layer 5 and the sealing layers SE11, SE12, SE13, and SE2 are formed, for example, from inorganic insulating materials such as silicon nitride (SiNx), silicon oxide (Siox), and silicon oxynitride (SiON).

The inorganic insulating layers, IL1, IL2, and IL3 are formed of an inorganic insulating material different from that of the rib layer 5, for example. In one example, the inorganic insulating layers, IL1, IL2, and IL3 are formed of silicon nitride, the rib layer 5 is formed of silicon nitride, and the sealing layers SE11, SE12, SE13, and SE2 are formed of silicon nitride. The resin layers RS1 and RS2 are formed of a resin material (organic insulating material) such as epoxy resin or acrylic resin.

The lower electrodes LE1, LE2, and LE3 are each a stacked layer body containing a transparent electrode formed from an oxide conductive material such as ITO and a metal electrode formed from a metal material such as silver. The upper electrodes UE1, UE2, and UE3 are formed from a metal material such as a magnesium-silver alloy (MgAg). For example, the lower electrodes LE1, LE2, and LE3 correspond to the anodes, and the upper electrodes UE1, UE2, and UE3 correspond to the cathodes.

The organic layers OR1, OR2, and OR3 are constituted by multiple thin films including a light-emitting layer. For example, the organic layers OR1, OR2, and OR3 have a structure in which a hole injection layer, a hole transport layer, an electron blocking layer, an emissive layer, a hole blocking layer, an electron transport layer, and an electron injection layer are sequentially stacked along the third direction Z. Note here that the organic layers OR1, OR2, and OR3 may as well have some other structure, such as the so-called tandem structure including multiple light-emitting layers.

The cap layers CP1, CP2, and CP3 have, for example, a stacked layer structure in which multiple transparent layers are stacked one on another. These transparent layers may include a layer formed from an inorganic material and a layer formed from an organic material. Further, these transparent layers have different refractive indices. For example, the refractive indices of these transparent layers are different from the refractive indices of the upper electrodes UE1, UE2, UE3 and those of the sealing layers SE11, SE12, SE13. Note that at least one of the cap layers CP1, CP2, CP3 may be omitted.

To the partition 6, a common voltage is supplied. This common voltage is supplied to each of the upper electrodes UE1, UE2, and UE3, which are in contact with the lower portion 61. To the lower electrodes LE1, LE2, and LE3, pixel voltages corresponding to the video signals of the signal lines SL are supplied through the pixel circuits 1 of the subpixels SP1, SP2, and SP3, respectively.

The organic layers OR1, OR2, and OR3 emit light according to the current flowing thereto. Specifically, when a current is allowed to flow between the lower electrode LE1 and the upper electrode UE1, the light-emitting layer of the organic layer OR1 emits light in a blue wavelength band. When a current is allowed to flow between the lower electrode LE2 and the upper electrode UE2, the light-emitting layer of the organic layer OR2 emits light in a green wavelength band. When a current is allowed to flow between the lower electrode LE3 and the upper electrode UE3, the light-emitting layer of the organic layer OR3 emits light in a red wavelength band.

As another example, the light-emitting layers of the organic layers OR1, OR2, and OR3 may emit light of the same color (for example, white). In this case, the display device DSP may comprise color filters that convert the light emitted by the light-emitting layers into light of colors corresponding to the subpixels SP1, SP2, and SP3. Further, the display device DSP may as well comprise a layer containing quantum dots that generate light of colors corresponding to the subpixels SP1, SP2, and SP3 when excited by the light emitted by the light-emitting layers.

The bottom layer 63 and the axis layer 64 are formed, for example, from a metal material. As the metal material for the bottom layer 63, for example, molybdenum (Mo), titanium (Ti), titanium nitride (TiN), molybdenum-tungsten alloy (MoW), or molybdenum-niobium alloy (MoNb) may be used. As the metal material for the axis layer 64, for example, aluminum (Al), aluminum-neodymium alloy (AlNd), aluminum-yttrium alloy (AlY), or aluminum-silicon alloy (AlSi) may be used. Note here that at least one of the bottom layer 63 and the axis layer 64 may have a stacked layer structure containing multiple layers. Additionally, the axial layer 64 may include a layer formed from an insulating material. Furthermore, it may have a single-layer structure in which the lower portion 61 is formed from a conductive material.

For example, the first top layer 65 is formed from a metal material, and the second top layer 66 is formed from a transparent conductive oxide. As the metal material of the first top layer 65, for example, titanium, titanium nitride, molybdenum, tungsten, molybdenum-tungsten alloy, or molybdenum-niobium alloy may be used. As the conductive oxide of the second top layer 66, for example, indium tin oxide (ITO), indium zinc oxide (IZO), or indium gallium zinc oxide (IGZO) can be used. Note that the upper portion 62 may have a single-layer structure formed from a specific material. Furthermore, the upper portion 62 may include a layer formed from an insulating material.

In the manufacturing of the display device DSP, a large-size mother board is fabricated, in which a plurality of regions (panel portions) each correspond to a display panel PNL. The configuration applicable to this mother board will be described.

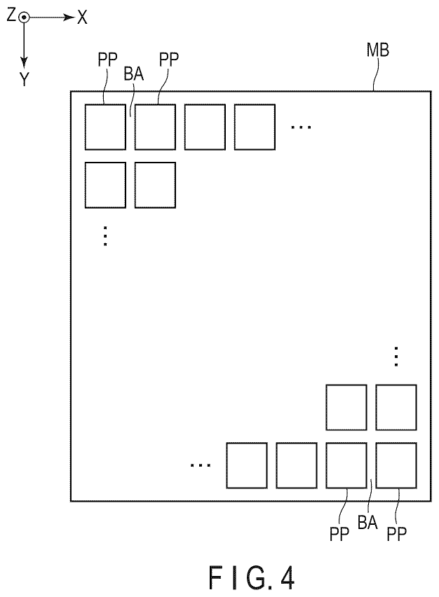

FIG. 4 is a plan view schematically showing a mother board MB (mother board for display device) according to this embodiment. The mother board MB is, for example, rectangular as shown, but may as well have some other shape such as circular.

The mother board MB includes a plurality of panel portions PP arranged in a matrix pattern and a blank area BA surrounding these panel portions PP. In the example shown in FIG. 4, a plurality of panel portions PP are aligned along the first direction X and the second direction Y via the blank area BA. Note that the arrangement of the panel portions PP on the mother board MB is not limited to that of this example.

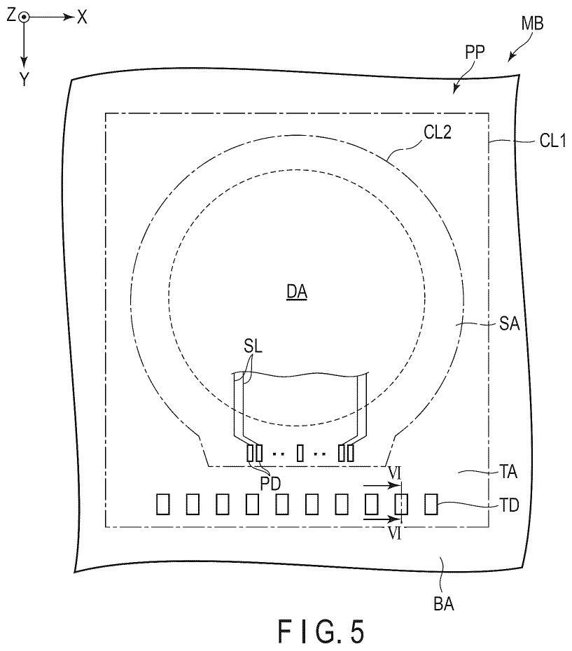

FIG. 5 is a plan view schematically showing a part of the mother board MB. This figure focuses on one panel portion PP. The outer shape of the panel portion PP corresponds to a cut line CL1 for cutting out the panel portion PP from the mother board MB.

The panel portion PP has the display area DA and the peripheral area SA described above. Further, the peripheral area SA includes an inspection area TA. In the inspection area TA, there are a plurality of inspection pads TD for inspecting the operation of the display panel PNL. The inspection pads TD each have, for example, a rectangular shape. The inspection pads TD are arranged at intervals along the first direction X.

On the panel portion PP, a cut line CL2 is formed. The cut line CL2 corresponds to the outer shape of the display panel PNL shown in FIG. 1. With the cut line CL2, the panel portion PP can be divided into a portion including the display area DA and a portion including the inspection area TA.

The inspection pads TD are disposed between the display area DA and the cut line CL1. From another perspective, the cut line CL2 is disposed between the display area DA and the inspection pads TD.

Although not shown, a plurality of inspection pads are disposed in the blank area BA as well. These inspection pads each may include an inspection pad for inspecting the operation of the display panel PNL and an inspection pad for measuring the thickness of a specific layer formed on the mother board MB. Further, a plurality of alignment marks may as well be arranged in the blank area BA.

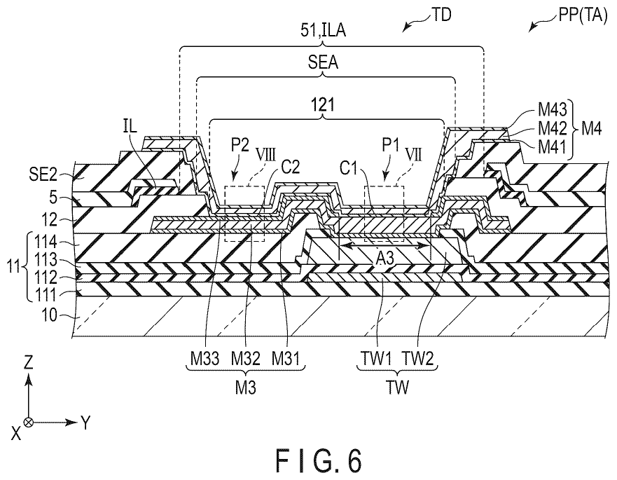

FIG. 6 is a cross-sectional view schematically showing the display device DSP taken along the line VI-VI in FIG. 5. FIG. 6 shows a part of the inspection area TA, which includes an inspection pad TD in the panel portion PP.

As described above, the display device DSP includes a circuit layer 11. The circuit layer 11 is disposed above the substrate 10, over the display area DA and to the peripheral area SA. The circuit layer 11 includes inorganic insulating layers 111, 112, and 113, an organic insulating layer 114, and wiring lines TW (inspection wiring lines). The wiring lines TW connect the inspection pad TD to the target to be inspected. The wiring lines TW include wiring lines TW1 and TW2.

The inorganic insulating layer 111 is disposed on the substrate 10. The wiring line TW1 is disposed on the inorganic insulating layer 111. The wiring line TW1 is formed, for example, in the same layer as that of the scanning lines GL. The inorganic insulating layer 112 is disposed on the inorganic insulating layer 111 and the wiring line TW1.

The wiring line TW2 is disposed on the inorganic insulating layer 112. The wiring line TW2 is formed, for example, in the same layer as that of the signal lines SL. The wiring line TW2 is electrically connected to the wiring line TW1 via a contact hole not shown. The inorganic insulating layer 113 is disposed on the inorganic insulating layer 112 and the wiring line TW2. The organic insulating layer 114 is disposed on the inorganic insulating layer 113.

The display device DSP further comprises a metal layer M3 (first metal layer). The metal layer M3 is disposed on the organic insulating layer 114. Further, at least a part of the metal layer M3 is located directly above the wiring line TW2.

The metal layer M3 is electrically connected to the wiring line TW2. Specifically, the metal layer M3 is in contact with the wiring line TW2 through an aperture in the inorganic insulating layer 113 and an aperture in the organic insulating layer 114.

The organic insulating layer 12 is disposed over the display area DA to the peripheral area SA. The organic insulating layer 12 is disposed on the organic insulating layer 114 and the metal layer M3. The organic insulating layer 12 has an aperture 121 (second aperture).

The display device DSP further comprises an inorganic insulating layer IL. The inorganic insulating layer IL is formed from the same material and the same manufacturing process as those of the inorganic insulating layers IL1, IL2, and IL3 in the display area DA. The inorganic insulating layer IL is disposed between the organic insulating layer 12 and the rib layer 5 in the inspection area TA. The inorganic insulating layer IL has an aperture ILA (third aperture).

The rib layer 5 is disposed over the display area DA to the peripheral area SA. The rib layer 5 is disposed on the organic insulating layer 12 and the inorganic insulating layer IL. From another perspective, the organic insulating layer 12 is disposed between the metal layer M3 and the rib layer 5. The rib layer 5 has a thickness greater than that of the inorganic insulating layer IL, for example. The rib layer 5 has an aperture 51 (first aperture).

The sealing layer SE2 is disposed over the display area DA to the peripheral area SA. The sealing layer SE2 is disposed on the rib layer 5. The sealing layer SE2 has an aperture SEA (fourth aperture).

The aperture 121 of the organic insulating layer 12, the aperture ILA of the inorganic insulating layer IL, the aperture 51 of the rib layer 5, and the aperture SEA of the sealing layer SE2 overlap each other. These apertures 121, ILA, 51, and SEA overlap the metal layer M3. In other words, the metal layer M3 is exposed through the apertures 121, ILA, 51, and SEA.

The display device DSP further includes a metal layer M4 (second metal layer). The inspection pads TD are each formed from the metal layer M3 and metal layer M4. The metal layer M4 is located directly above metal layer M3 and is electrically connected to the metal layer M3. In other words, the metal layer M4 is in contact with the metal layer M3 in the apertures 121, ILA, 51, and SEA. Focusing on the rib layer 5, the rib layer 5 is disposed between the metal layer M3 and the metal layer M4.

Here, the configuration of the metal layers M3 and M4 will be described. The metal layers M3 and M4 are each a multi-layered body including a plurality of layers formed from different metal materials.

The metal layer M3 includes a first layer M31 overlaid on the organic insulating layer 114, a second layer M32 overlaid on the first layer M31, and a third layer M33 overlaid on the second layer M32. The first layer M31 and the third layer M33 are formed from the first metal material, and the second layer M32 is formed from the second metal material.

The first layer M31 is in contact with the wiring line TW2. The third layer M33 has an area A3 that exposes the second layer M32 of the metal layer M3. The area A3 is located directly above the wiring line TW2.

The metal layer M4 includes a fourth layer M41 overlaid on the metal layer M3, a fifth layer M42 overlaid on the fourth layer M41, and a sixth layer M43 overlaid on the fifth layer M42. The fourth layer M41 and the sixth layer M43 are formed from the first metal material, and the fifth layer M42 is formed from the second metal material. Here, for example, the first metal material is a titanium-based material, and the second metal material is an aluminum-based material, but the first metal material and the second metal material are not limited to those of this example.

Further, the fourth layer M41 of the metal layer M4 includes a first contact portion C1 in contact with the second layer M32 and a second contact portion C2 in contact with the third layer M33. The first contact portion C1 and the second contact portion C2 are located on an inner side of the aperture 121 of the organic insulating layer 12.

The first contact portion C1 overlaps the area A3. The second contact portion C2 does not overlap the area A3. The first contact portion C1 is located above the wiring line TW, and the second contact portion C2 is not located above the wiring line TW. Focusing on the inspection pad TD, the inspection pad TD has a first portion P1 containing the first contact portion C1 and a second portion P2 containing the second contact portion C2, formed thereon.

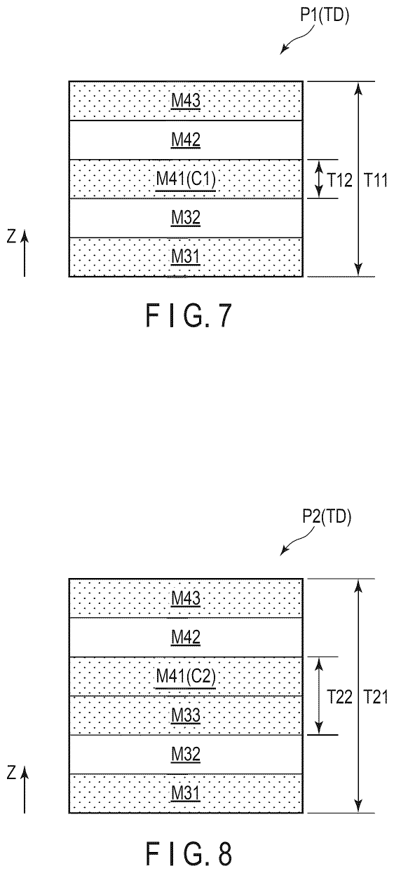

FIG. 7 is a partial enlarged view showing the portion VII in FIG. 6. FIG. 8 is a partial enlarged view showing the portion VIII in FIG. 6. FIG. 7 shows the first portion P1 of the inspection pad TD, and FIG. 8 shows the second portion P2 of the inspection pad TD.

The first portion P1 is constituted by the first layer M31, the second layer M32, the fourth layer M41, the fifth layer M42, and the sixth layer M43, stacked one on another, as shown in FIG. 7. The second portion P2, as shown in FIG. 8, is constituted by the first layer M31, the second layer M32, the third layer M33, the fourth layer M41, the fifth layer M42, and the sixth layer M43, which are stacked one on another.

The second portion P2 has a thickness T21 which is greater than a thickness T11 of the first portion P1. The distance between the second layer M32 and the fifth layer M42 in the second portion P2 is greater than the distance between the second layer M32 and the fifth layer M42 in the first portion P1.

In other words, the layer formed from the second metal material between the second layer M32 and the fifth layer M42 in the second portion P2 has a thickness T22 which is greater than a thickness T12 of the layer formed from the second metal material between the second layer M32 and the fifth layer M42 in the first portion P1.

The inorganic insulating layers 111, 112, and 113 are formed from one of silicon oxide, silicon nitride, and silicon nitride oxide. The wiring line TW2 is formed from a plurality of layers, for example. The wiring line TW2 is formed in a way similar to that of the metal layers M3 and M4, for example.

Note that at least one of the wiring line TW2, metal layers M3 and M4 may be formed by arranging an aluminum layer between layers formed of molybdenum-based materials. The organic insulating layer 114 is formed from an organic insulating material such as polyimide.

Next, an example of a method of manufacturing the display device DSP will be described.

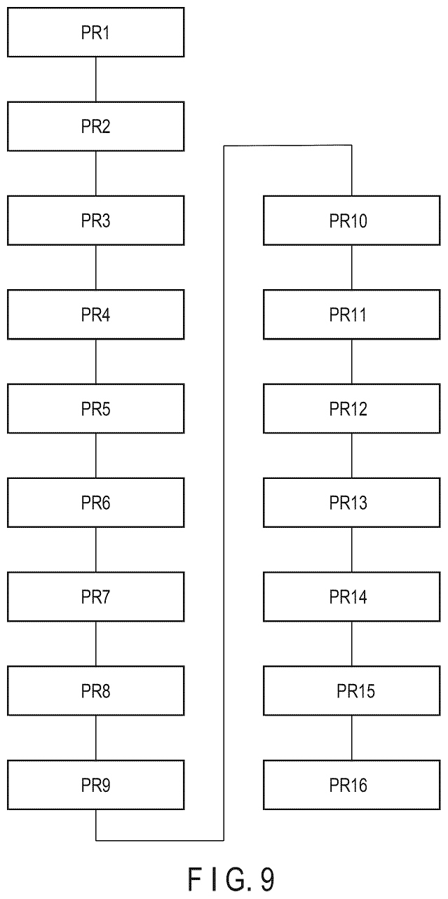

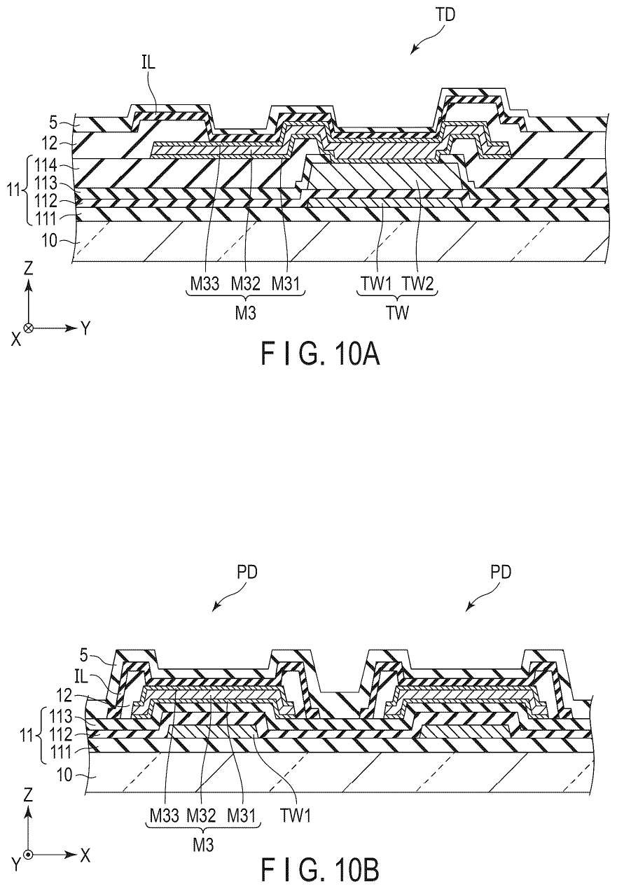

FIG. 9 is a flowchart showing an example of the method of manufacturing the display device DSP. FIGS. 10A to 20B are schematic cross-sectional views showing processing steps in the manufacturing of the display device DSP. FIGS. 10A, 11A, 12A, 13A, 14A, 15A, 16A, 17A, 18A, 19A, and 20A focus primarily on the inspection pads TD, while FIGS. 10B, 11B, 12B, 13B, 14B, 15B, 16B, 17B, 18B, 19B, and 20B focus primarily on the pads PD.

In the formation of the panel portion PP, the circuit layer 11 and the metal layer M3 are first formed on the substrate 10 of the mother board MB (processing step PR1 in FIG. 9). The processing step PR1 includes the preparation of the substrate 10 having the panel portion PP.

The circuit layer 11 includes inorganic insulating layers 111, 112, 113, an organic insulating layer 114, and a wiring line TW. The circuit layer 11 is formed over the entire mother board MB, including not only the display area DA but also the peripheral area SA.

The metal layer M3 is formed in the peripheral area SA, including the inspection area TA, as shown in FIGS. 10A and 10B. The process of forming the metal layer M3 includes forming of the first layer M31 from the first metal material, forming of the second layer M32 from the second metal material, forming of the third layer M33 from the first metal material, and patterning of the first layer M31, the second layer M32, and the third layer M33. The first layer M31, second layer M32, and third layer M33 are formed, for example, by sputtering.

Next, the organic insulating layer 12 is formed above the circuit layer 11 and the metal layer M3 (processing step PR2 in FIG. 9). The organic insulating layer 12 is formed over the entire mother board MB, including not only the display area DA but also the peripheral area SA. The processing step PR2 includes patterning of the organic insulating layer 12. The organic insulating layer 12 has the aperture 121 (shown in FIG. 6).

Next, as shown in FIGS. 10A and 10B, the inorganic insulating layer IL and the rib layer 5 are formed above the organic insulating layer 12 and the metal layer M3 (processing step PR3 in FIG. 9).

The rib layer 5 is formed over the entire surface of the mother board MB. The rib layer 5 can be formed by chemical vapor deposition (CVD).

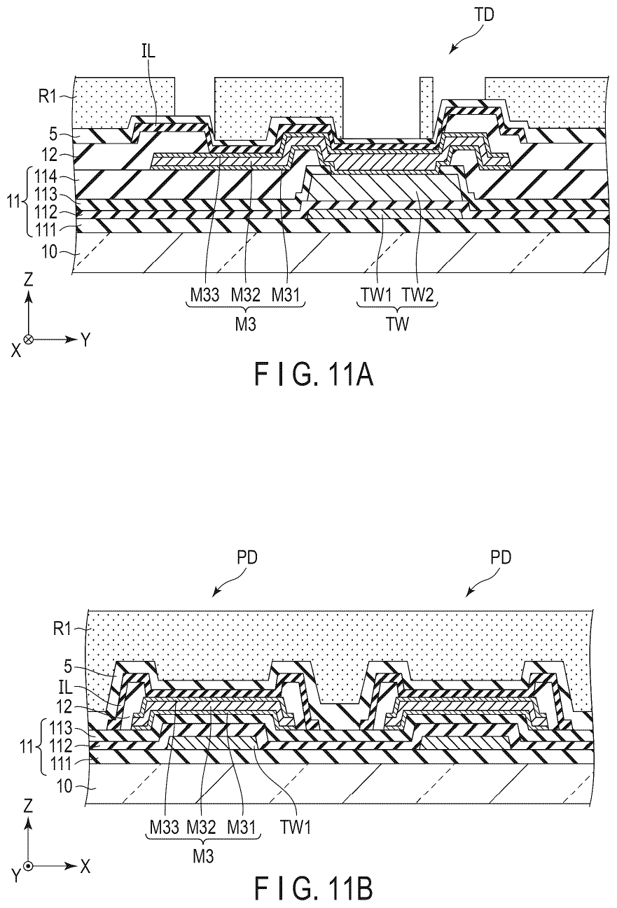

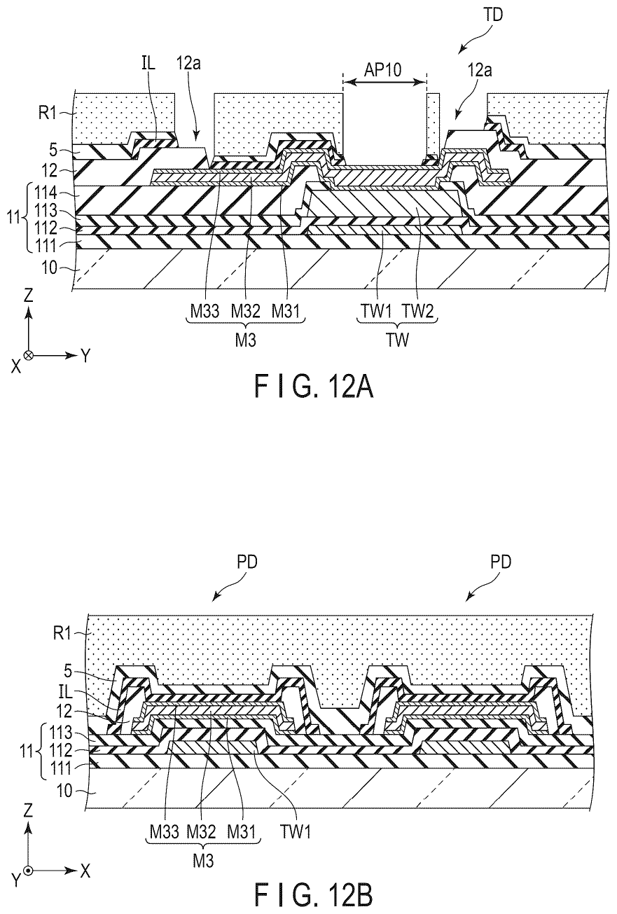

After the processing step PR3, a step for forming an inspection aperture AP10 is performed (processing step PR4 in FIG. 9). In the processing step PR4, a resist R1 is placed on the rib layer 5. The resist R1 has such a shape that is open above the wiring line TW and above a step portion 12a of the organic insulating layer 12 (shown in FIG. 12A), as shown in FIG. 11A. In contrast, the resist R1 is not open above the pad PD, as shown in FIG. 11B.

After that, dry etching is performed on the rib layer 5 and the inorganic insulating layer IL using the resist R1 as a mask. With this operation, the portions of the rib layer 5 and the inorganic insulating layer IL, which are exposed from the resist R1 are removed.

After the processing step PR4, as shown in FIG. 12A, the inspection aperture AP10 is formed in the rib layer 5 and the inorganic insulating layer IL so as to overlap the metal layer M3. The inspection aperture AP10 is formed in the region overlapping the wiring line TW, of the region overlapping the metal layer M3.

Further, in the region overlapping the step portion 12a of the organic insulating layer 12, the rib layer 5 and the inorganic insulating layer IL are removed. With this configuration, a sealing layer SE2, which will be described later, adheres tightly to the step portion 12a of the organic insulating layer 12 and does not easily peel off.

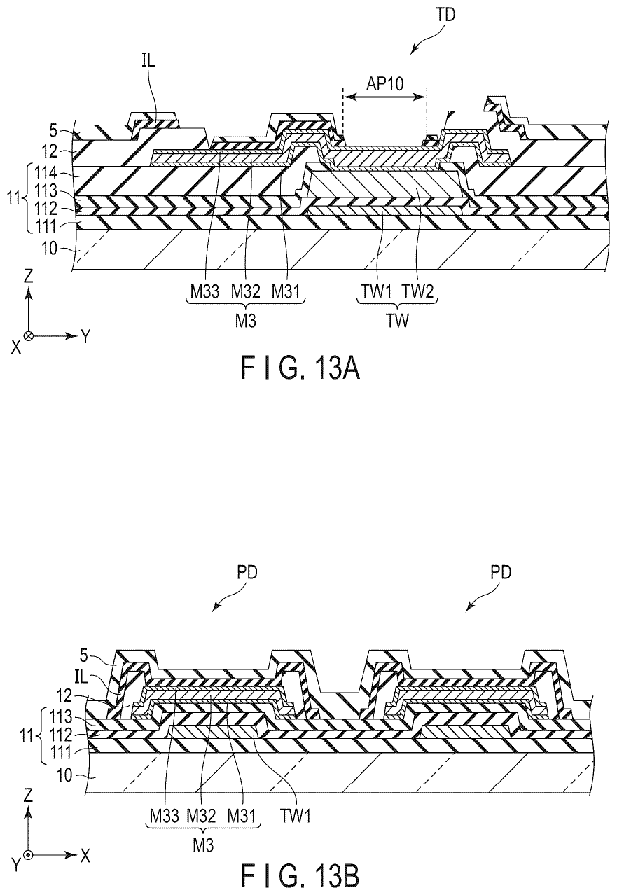

Further, the rib layer 5 and the inorganic insulating layer IL overlapping the pad PD are not removed. After the above-described dry etching, the resist R1 is removed (peeled off) as shown in FIGS. 13A and 13B.

After the processing step PR4, as shown in FIG. 13A, a part of the metal layer M3 of the inspection pad TD is exposed, but as shown in FIG. 13B, the metal layer M3 of the pad PD is not exposed. The metal layer M3 of the pad PD is covered by the inorganic insulating layer IL and the rib layer 5, and with this configuration, the metal layer M3 is protected in subsequent processing steps (where the display elements DE1, DE2, and DE3 are formed).

After the processing step PR4, steps for forming the display elements DE1, DE2, and DE3 are performed (processing steps PR5 to PR7 in FIG. 9). After the formation of the display elements DE1, DE2, and DE3, lighting inspection of the display elements DE1, DE2, and DE3 is performed using the exposed metal layer M3 through the inspection aperture AP10 of the inspection pad TD (processing step PR8 in FIG. 9).

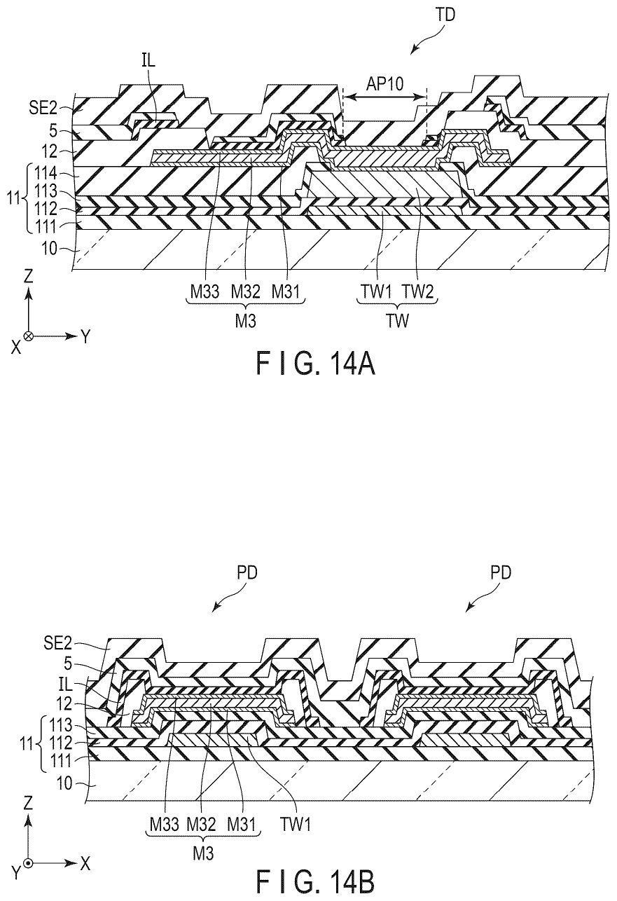

After the processing step PR8, a sealing layer SE2 covering the rib layer 5 is formed as shown in FIGS. 14A and 14B (processing step PR9 in FIG. 9). The sealing layer SE2 is formed over the entire mother board MB, for example by CVD. The sealing layer SE2 covers the inspection aperture AP10 as shown in FIG. 14A. In other words, the sealing layer SE2 is in contact with the metal layer M3 in the inspection aperture AP10.

After the processing step PR9, a step of forming an aperture exposing the metal layer M3 is performed (processing step PR10 in FIG. 9). In other words, a step of removing the sealing layer SE2, rib layer 5, and inorganic insulating layer IL in the pad PD and the inspection pad TD is performed.

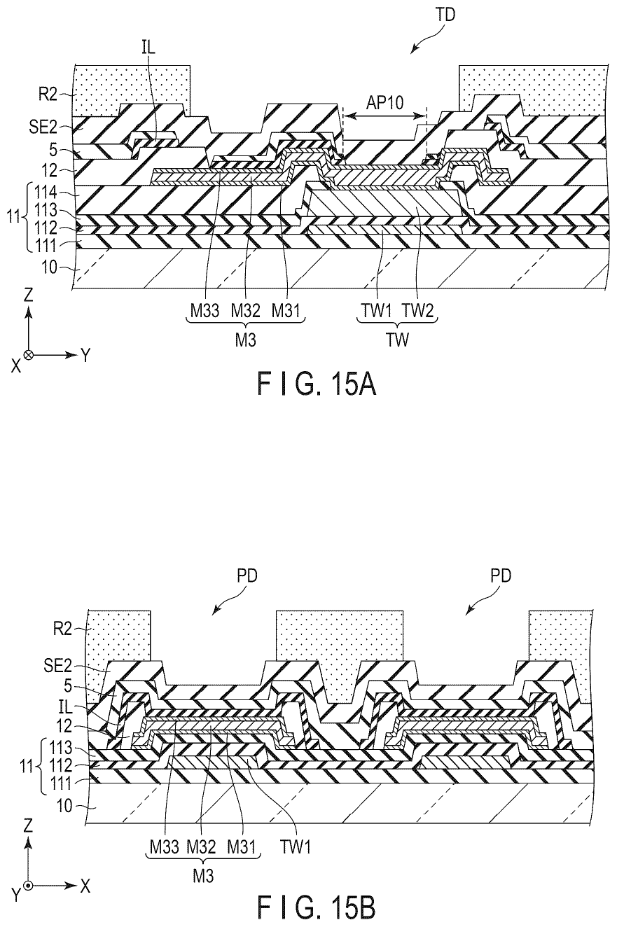

In the processing step PR10, a resist R2 is placed on the sealing layer SE2. The resist R2 has such a shape that is open above the pad PD and inspection pad TD, as shown in FIGS. 15A and 15B.

After that, dry etching is performed on the sealing layer SE2, rib layer 5, and inorganic insulating layer IL using the resist R2 as a mask. With this operation, the portions of the sealing layer SE2, rib layer 5, and inorganic insulating layer IL, which are exposed from the resist R2 are removed.

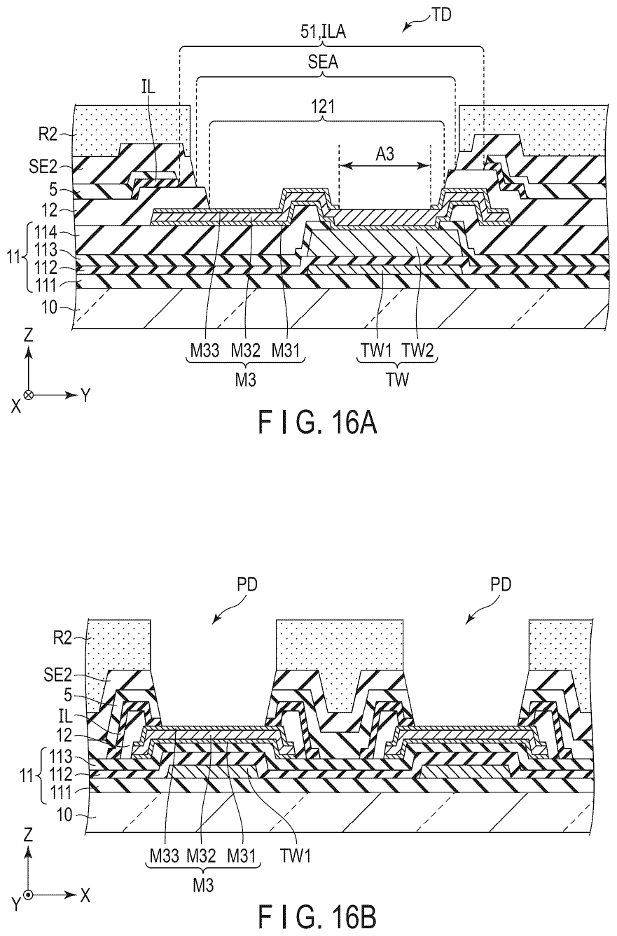

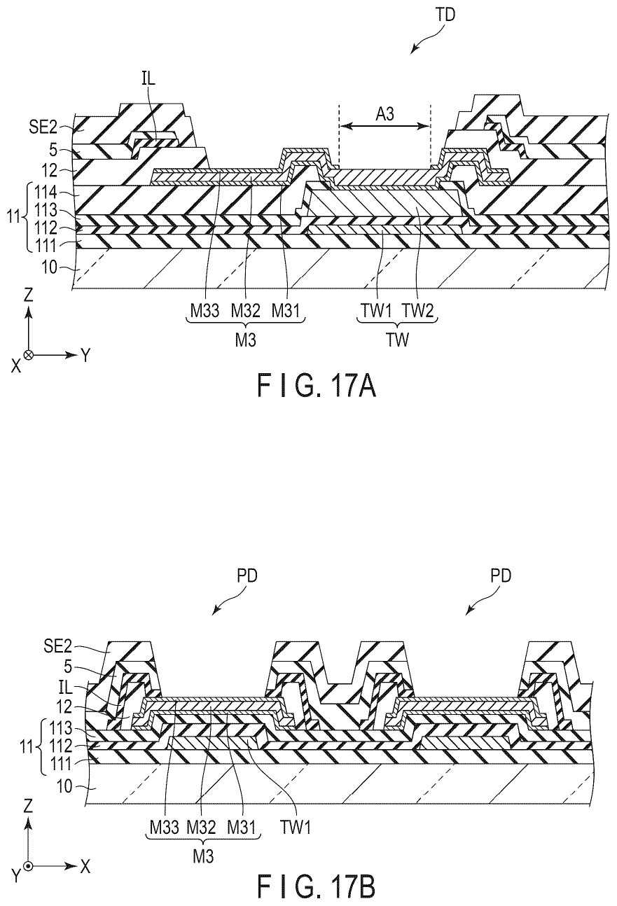

After the processing step PR10, as shown in FIGS. 16A and 16B, apertures overlapping the metal layer M3 are formed in the rib layer 5, inorganic insulating layer IL, and sealing layer SE2. Focusing on the inspection pad TD, the aperture 51 is formed in the rib layer 5, the aperture ILA is formed in the inorganic insulating layer IL, and the aperture SEA is formed in the sealing layer SE2. Focusing on the pad PD, the metal layer M3 is exposed. After the above-described etching, the resist R2 is removed as shown in FIGS. 17A and 17B.

After the processing step PR10, the region of the third layer M33 of the metal layer M3, which overlaps the inspection aperture AP10, is subjected to dry etching at least twice. With this operation, the third layer M33 overlapping the inspection aperture AP10 is removed, and thus an area A3 is formed. As described above, the second layer M32 of the metal layer M3 is exposed from the area A3. The area A3 has an area equivalent to that of the inspection aperture AP10, for example.

Next, after the processing step PR10, the lighting inspection of the display elements DE1, DE2, and DE3 is performed using the metal layer M3 of the inspection pad TD (processing step PR11 in FIG. 9).

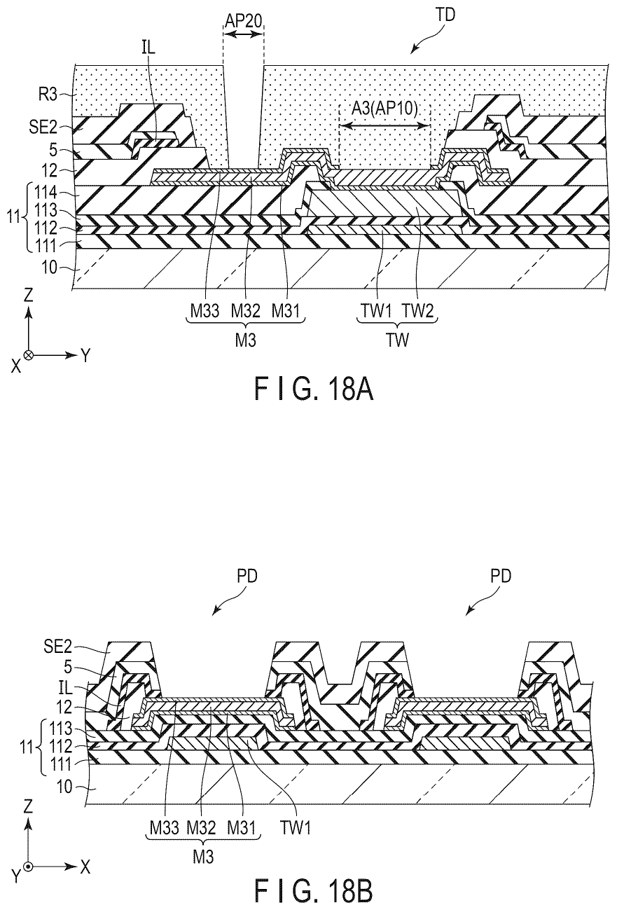

After the processing step PR11, a step for removing the sealing layer SE2 in the pad PD is performed (processing step PR12 in FIG. 9). In the processing step PR12, a resist R3 is placed on the sealing layer SE2. The resist R3 covers the aperture 121 of the organic insulating layer 12, the aperture 51 of the rib layer 5, the aperture ILA of the inorganic insulating layer IL, and the aperture SEA of the sealing layer SE2. The resist R3 is not located above the pads PD, as shown in FIG. 18B.

The resist R3 has such a shape that is open above the inspection pad TD, as shown in FIG. 18A. Specifically, the resist R3 has an aperture AP20. In this embodiment, the aperture AP20 is an example of a cleaning aperture.

The third layer M33 of the metal layer M3 is exposed through the aperture AP20. Focusing on the inspection aperture AP10, the location where the aperture AP20 is formed does not overlap the position where the inspection aperture AP10 is formed. After that, dry etching is performed on the sealing layer SE2 using the resist R3 as a mask.

After the processing step PR12, in the area including the pads PD (for example, each portion between adjacent pads PD), the sealing layer SE2 is removed. In contrast, in the inspection pad TD, the oxide film on the surface of the third layer M33 of the metal layer M3 exposed from the aperture AP20 is removed. In other words, the surface of the third layer M33 is cleaned by dry etching. The processing step PR12 corresponds to the step for cleaning the metal layer M3.

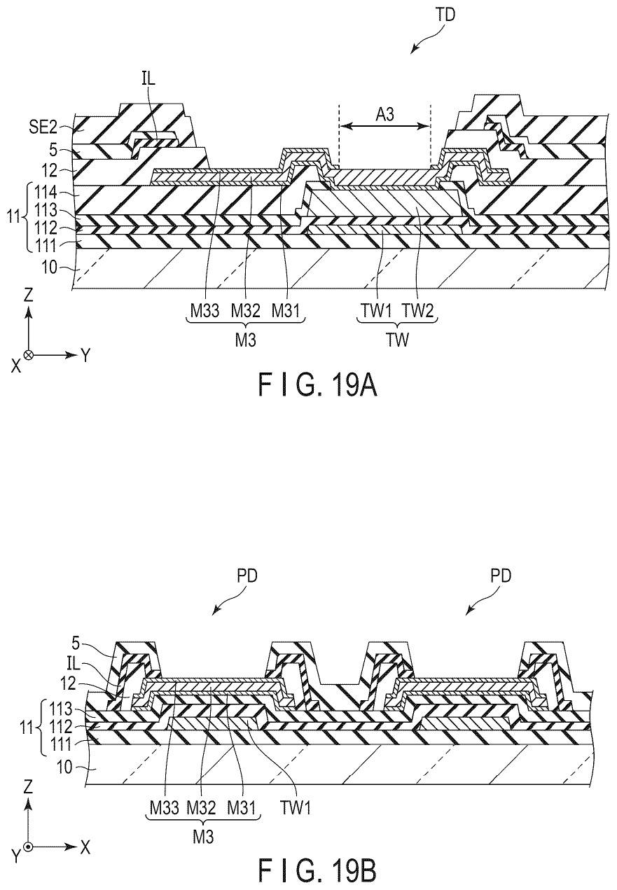

Further, the etching in the processing step PR12 is performed at such an intensity that the third layer M33 exposed from the aperture AP20 does not disappear. After the above-described dry etching, the resist R3 is removed as shown in FIGS. 19A and 19B.

After the processing step PR12, a step for forming the metal layer M4 is performed (processing step PR13 in FIG. 9). The processing step PR13 includes forming of the fourth layer M41 using the first metal material, forming of the fifth layer M42 using the second metal material, forming of the sixth layer M43 using the first metal material, and patterning of the fourth layer M41, the fifth layer M42, and the sixth layer M43. The fourth layer M41, the fifth layer M42, and the sixth layer M43 are formed, for example, by sputtering.

From another perspective, in the processing step PR13, the first portion P1 (shown in FIG. 6) and the second portion P2 (shown in FIG. 6) are formed in the inspection pad TD. Further, the second contact portion C2 (shown in FIG. 6) corresponds to the portion overlapping the region where the aperture AP20 is formed (the region where the oxide film has been removed from the surface of the third layer M33).

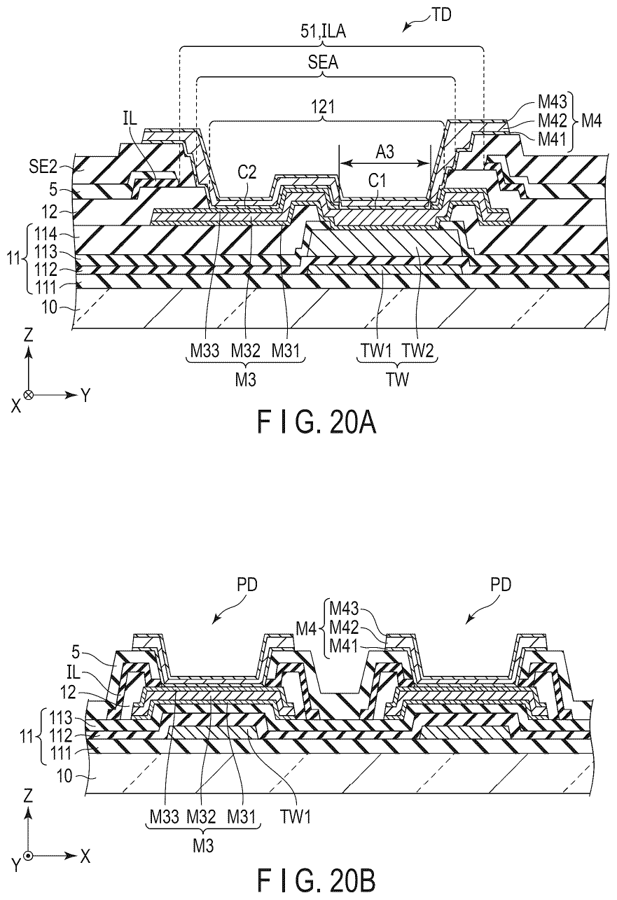

In the example shown in FIG. 20A, the second contact portion C2 is provided offset in a direction opposite to the second direction Y with respect to the first contact portion C1. Note that the second contact portion C2 may as well be provided offset in any of the first direction X, the direction opposite to the first direction X, and the second direction Y with respect to the first contact portion C1.

After the processing step PR13, as shown in FIGS. 20A and 20B, the inspection pad TD and the pads PD, which include the metal layer M4, are formed. Then, after the processing step for forming the resin layer RS2 (processing step PR14 in FIG. 9) and the like, each of the panel portions PP is cut out from the mother board MB along the cut line CL1 (processing step PR15 in FIG. 9). Subsequently, the inspection area TA (inspection pads TD) is separated from the peripheral area SA along the cut line CL2 (processing step PR16 in FIG. 9). Thus, the display panel PNL is completed.

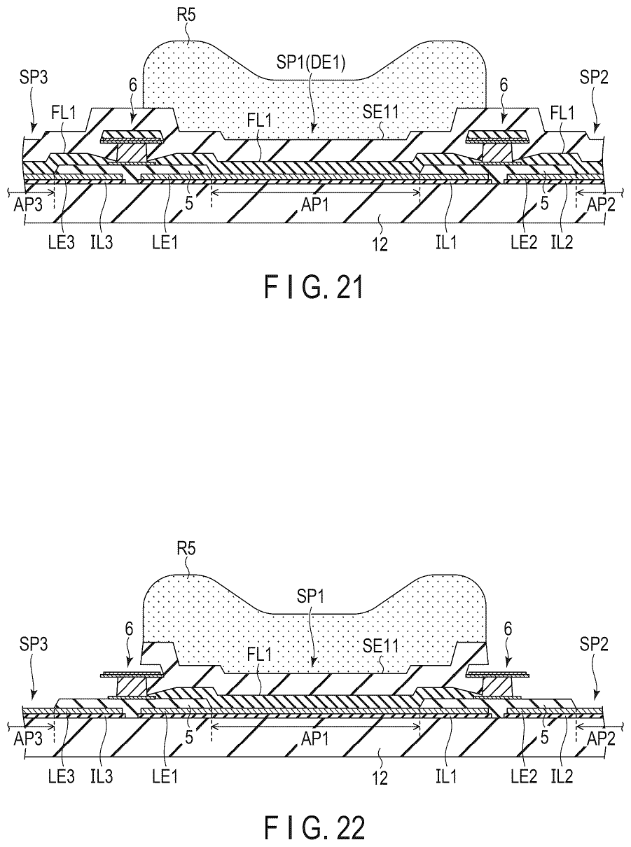

FIGS. 21 to 24 are schematic cross-sectional views showing the processing steps for forming display elements DE1, DE2, and DE3, respectively. In FIGS. 21 to 24, the subpixels SP1, SP2, and SP3 are mainly focused. Note that in FIGS. 21 to 24, elements located below the organic insulating layer 12 are omitted from illustration. At the completion of the processing step PR4, as shown in FIG. 21, a partition 6 is formed on the rib layer 5 in the display area DA.

Then, the step for forming the display element DE1 is performed (processing step PR5 in FIG. 9). In the formation of the display element DE1, as shown in FIG. 21, the stacked-layered film FL1 and the sealing layer SE11 are formed. The stacked-layered film FL1 includes an organic layer OR1 in contact with the lower electrode LE1 through the pixel aperture AP1, an upper electrode UE1 covering the organic layer OR1, and a cap layer CP1 covering the upper electrode UE1, as shown in FIG. 3. The organic layer OR1, the upper electrode UE1, and the cap layer CP1 can be formed, for example, by vapor deposition. Further, the sealing layer SE11 can be formed, for example, by CVD.

The stacked-layered film FL1 and the sealing layer SE11 are formed over the entire mother board MB, including not only the display area DA of each panel portion PP but also the peripheral area SA and the blank area BA. The stacked-layered film FL1 is divided into a plurality of sections by the overhanging partition 6. The sealing layer SE11 continuously covers each of the divided sections of the stacked-layered film FL1 and the partition 6.

Next, the stacked-layered film FL1 and the sealing layer SE11 are patterned. In this patterning, as shown in FIG. 21, a resist R5 is placed on the sealing layer SE11. The resist R5 covers the sub-pixel SP1 and part of the partition 6 surrounding it.

After that, an etching step is performed using the resist R5 as a mask. With this operation, as shown in FIG. 22, the portions of the stacked-layered film FL1 and the sealing layer SE11, which are exposed from the resist R5 are removed. In other words, the portions of the stacked-layered film FL1 and the sealing layer SE11, which overlap with the lower electrode LE1 remain, while the other portions are removed. With this operation, the display element DE1 is formed in the sub-pixel SP1. For example, in the peripheral area SA and the blank area BA, the stacked-layered film FL1 and the sealing layer SE11 are removed by the etching step. The etching step may include wet etching and dry etching performed sequentially on the sealing layer SE11, the cap layer CP1, the upper electrode UE1, and the organic layer OR1. After these etching steps, the resist R5 is removed.

After the processing step PR5, a step for forming the display element DE2 is performed (processing step PR6 in FIG. 9). The display element DE2 can be formed by a procedure similar to that for the display element DE1. That is, in the formation of the display element DE2, the stacked-layered film FL2 and the sealing layer SE12 are formed over the entire mother board MB. The stacked-layered film FL2 includes an organic layer OR2 in contact with the lower electrode LE2 through the pixel aperture AP2, an upper electrode UE2 covering the organic layer OR2, and a cap layer CP2 covering the upper electrode UE2, as shown in FIG. 3.

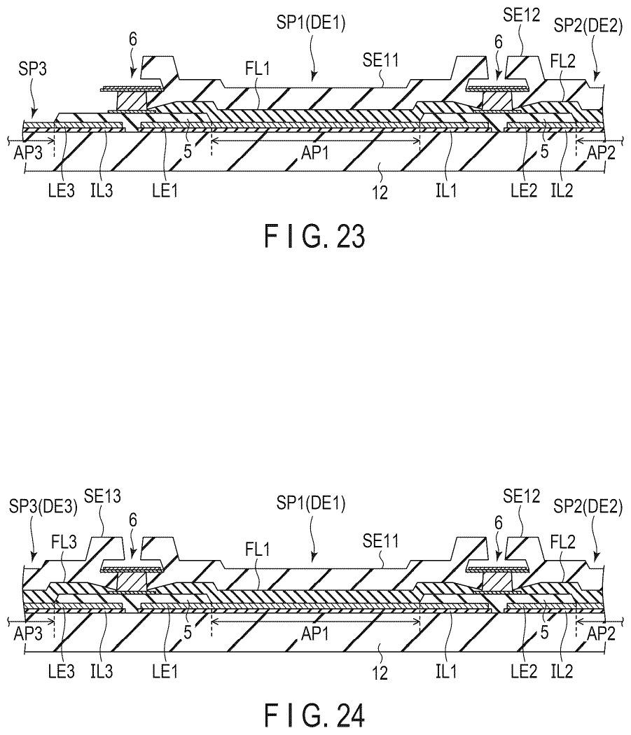

The organic layer OR2, upper electrode UE2, and cap layer CP2 can be formed, for example, by vapor deposition. Further, the sealing layer SE12 can be formed, for example, by CVD. The stacked-layered film FL2 is divided into a plurality of sections by the overhanging partition 6. The sealing layer SE12 continuously covers each of the divided sections of the stacked-layered film FL2 and the partition 6. By patterning the stacked-layered film FL2 and the sealing layer SE2 as described above, the display element DE2 is formed in the subpixel SP2 as shown in FIG. 23. For example, in the peripheral area SA and the blank area BA, the stacked-layered film FL2 and the sealing layer SE12 are removed by the etching in the patterning step.

After the processing step PR6, a step for forming the display element DE3 is performed (processing step PR7 in FIG. 9). The display element DE3 can be formed using a procedure similar to those for the display elements DE1 and DE2. That is, in the formation of the display element DE3, the stacked-layered film FL3 and the sealing layer SE13 are formed over the entire mother board MB. The stacked-layered film FL3 includes an organic layer OR3 in contact with the lower electrode LE3 through the pixel aperture AP3, an upper electrode UE3 covering the organic layer OR3, and a cap layer CP3 covering the upper electrode UE3, as shown in FIG. 3.

The organic layer OR3, upper electrode UE3, and cap layer CP3 can be formed, for example, by vapor deposition. Further, the sealing layer SE13 can be formed, for example, by CVD. The stacked-layered film FL3 is divided into a plurality of sections by the overhanging partition 6. The sealing layer SE13 continuously covers each of the divided sections of the stacked-layered film FL3 and the partition 6. By patterning the stacked-layered film FL3 and the sealing layer SE13 as described above, the display element DE3 is formed in the subpixel SP3 as shown in FIG. 24. For example, in the peripheral area SA and the blank area BA, the stacked-layered film FL3 and the sealing layer SE13 are removed by the etching in the patterning step.

Note that here, it is assumed that the display elements DE1, DE2, and DE3 are formed in this order, but the display elements DE1, DE2, and DE3 may as well be formed in some other order.

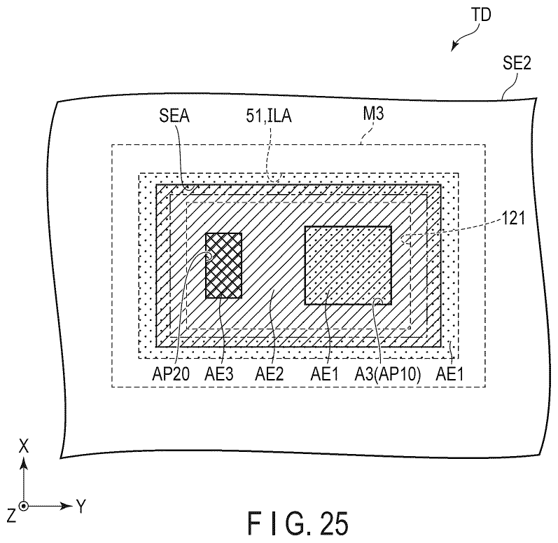

FIG. 25 is a diagram illustrating the apertures 121, ILA, 51, and SEA, which overlap the inspection pads TD. In FIG. 25, part of the elements such as the metal layer M4 is omitted.

The area of the aperture 121 in the organic insulating layer 12 is smaller than the area of the aperture 51 in the rib layer 5 in plan view. The aperture ILA of the inorganic insulating layer IL has an area, in plan view, equivalent to that of the aperture 51. In other words, the edge of the aperture ILA is aligned with the edge of the aperture 51. The area of the aperture SEA of the sealing layer SE2 is smaller than the area of the aperture 51 or ILA, and larger than the area of the aperture 121, in plan view.

Further, as shown in FIG. 25, it is assumed that the region where dry etching is performed in the processing step PR4 is defined as an area AE1, the region where dry etching is performed in the processing step PR10 is defined as an area AE2, and the region where dry etching is performed in the processing step PR12 is defined as an area AE3.

In FIG. 25, the area AE1 is hatched with dots, the area AE2 is hatched with diagonal lines, and the area AE3 is hatched with crosses.

The outer shape of the area AE1 corresponds to the edges of the apertures 51 and ILA. The inner region of the area AE1 overlaps the inspection aperture AP10 (area A3 of the metal layer M3). The outer shape of the area AE2 corresponds to the edges of the aperture SEA of the sealing layer SE2. The area AE3 overlaps the aperture AP20 of the resist R3. As described above, the location where the aperture AP20 is formed does not overlap the location where the inspection aperture AP10 is formed.

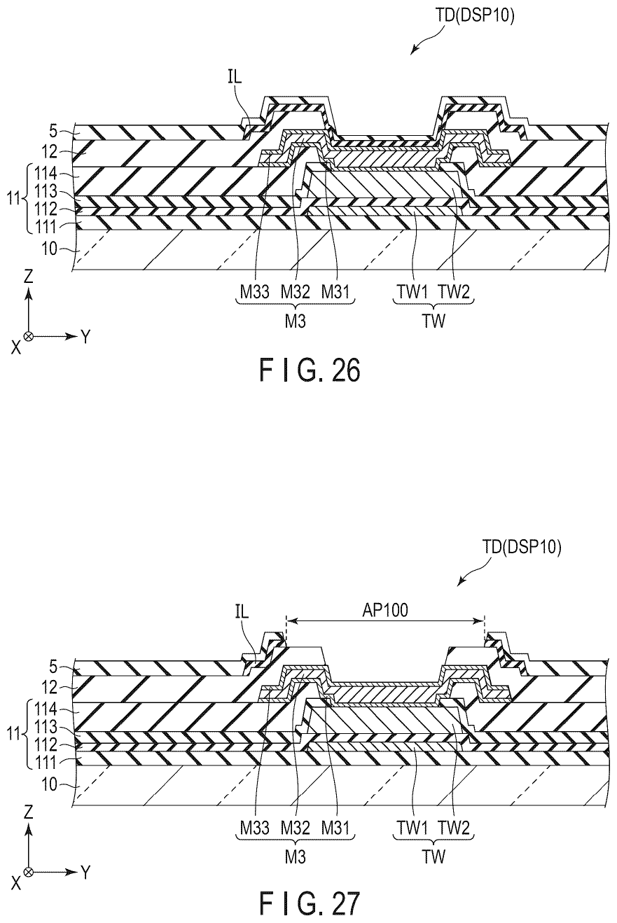

FIGS. 26 to 30 are schematic cross-sectional views showing processing steps in the manufacturing of a display device DSP10 according to a comparative example. FIGS. 26 to 30 focus primarily on the inspection pads TD.

First, as shown in FIG. 26, a circuit layer 11, a metal layer M3, an organic insulating layer 12, an inorganic insulating layer IL, and a rib layer 5 are formed on a substrate 10 of a mother board MB.

Next, a step for forming an aperture AP100 in the inorganic insulating layer IL and the rib layer 5 is performed. In this step, a resist having such a shape that is open above the inspection pad TD is placed on the rib layer 5. After that, dry etching is performed on the rib layer 5 and the inorganic insulating layer IL using the resist as a mask.

With this operation, the portions of the rib layer 5 and the inorganic insulating layer IL, which are exposed from the resist are removed. After this step, the aperture AP100 is formed in the rib layer 5 and inorganic insulating layer IL, as shown in FIG. 27. The metal layer M3 is exposed through the aperture AP100.

Next, steps for forming the display elements DE1, DE2, and DE3 and a step for lighting inspection are performed, and thus a sealing layer SE2 covering the rib layer 5 is formed. The sealing layer SE2 covers the aperture AP100.

Next, a step for removing the sealing layer SE2 in the inspection pad TD is performed. In this step, a resist having such a shape that is open above the inspection pad TD is placed on the sealing layer SE2.

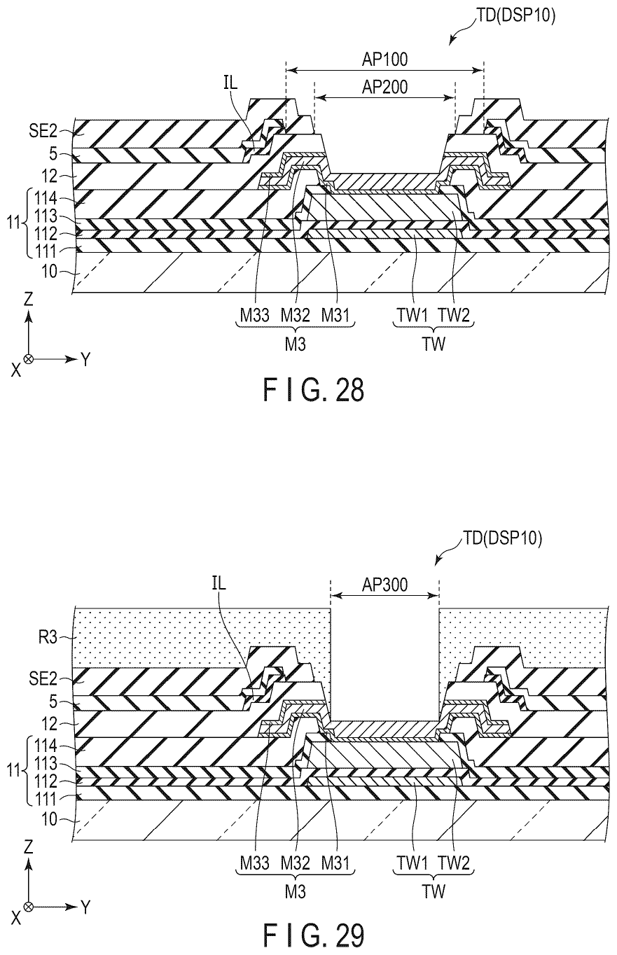

After that, dry etching is performed on the sealing layer SE2 using the resist as a mask. With this operation, the portion of the sealing layer SE2, which is exposed from the resist is removed. After this step, as shown in FIG. 28, the aperture AP200 is formed in the sealing layer SE2.

The third layer M33 overlapping the aperture AP200 is subjected to dry etching at least twice. With this operation, the third layer M33 is removed in the region overlapping the aperture AP200, and thus the second layer M32 of the metal layer M3 is exposed from the aperture AP200.

Next, a step for removing the sealing layer SE2 in the pad PD is performed. Focusing on the inspection pad TD, as shown in FIG. 29, a resist R3 having such a shape that is open above the inspection pad TD is placed on the sealing layer SE2. In other words, the resist R3 has an aperture AP300.

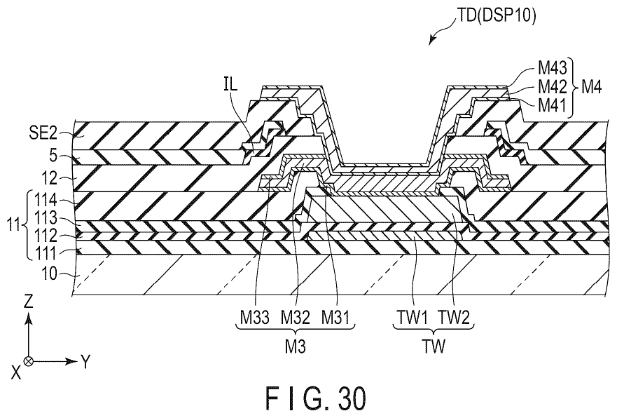

The location where the aperture AP300 is formed overlaps the above-described apertures AP100 and AP200. From the aperture AP300, the second layer M32 of the metal layer M3 is exposed. In this step, the second layer M32 formed from an aluminum-based material is dissolved out by the resist developer, or the surface of the exposed second layer M32 is oxidized. Subsequently, as shown in FIG. 30, a step for forming the metal layer M4 is performed.

In the display device DSP10 according to the comparative example, the fourth layer M41 of the metal layer M4 is in contact with the second layer M32 of the metal layer M3, as shown in FIG. 30. The second layer M32 in contact with the fourth layer M41 is, for example, oxidized.

The oxidized second layer M32 has high resistance, and therefore the connection resistance between the metal layer M3 and the metal layer M4 increases. With this configuration, there is a risk that a poor electrical contact between the metal layer M3 and the metal layer M4 may occur. Using such an inspection pad TD to inspect the display area DA and the like, may be a factor of lowering the reliability of the mother board and the display device.

In this embodiment, the metal layer M4 has a second contact portion C2 in contact with the third layer M33 of the metal layer M3. The second contact portion C2 is brought into contact with the metal layer M3, rather than the oxidized second layer M32, and therefore the connection resistance between the metal layer M3 and the metal layer M4 can be reduced.

With this configuration, an inspection pad TD stably connected with the metal layer M3 and the metal layer M4 can be formed on the mother board MB. By using such an inspection pad TD, the display area DA (for example, display elements DE1, DE2, DE3 and the like) can be reliably inspected. As a result, the decrease in the reliability of the mother board MB and the display device DSP can be suppressed.

Further, in the manufacturing method according to this embodiment, the location where the aperture AP20 (shown in FIG. 18A) is formed does not overlap the location where the inspection aperture AP10 (shown in FIG. 13A) is formed.

Thus, the third layer M33 of the metal layer M3 is exposed from the aperture AP20. With this configuration, in the processing step PR12, the oxide film on the surface of the third layer M33, which is exposed through the aperture AP20 can be removed (cleaning). As a result, an error in the electrical contact between the metal layer M3 and metal layer M4 does not even more easily occur. In other words, in this embodiment, a contact portion can be formed in which errors in the electrical contact between the metal layer M3 and the metal layer M4 are less likely to occur.

Further, the second layer M32 is not exposed from the aperture AP20. Therefore, compared to the method of manufacturing the display device DSP10 of the comparative example described with reference to FIG. 29, the dissolution of the second layer M32 of the metal layer M3 can be suppressed.

With the mother board MB, display device DSP, and manufacturing method of the display device DSP configured as described above, a decrease in reliability can be suppressed. Various other advantageous effects can be obtained from this embodiment.

### Second Embodiment

The second embodiment will now be described. For the display device DSP, mother board MB, and method of manufacturing the display device DSP not referred to in this embodiment, a configuration similar to that of the first embodiment can be applied.

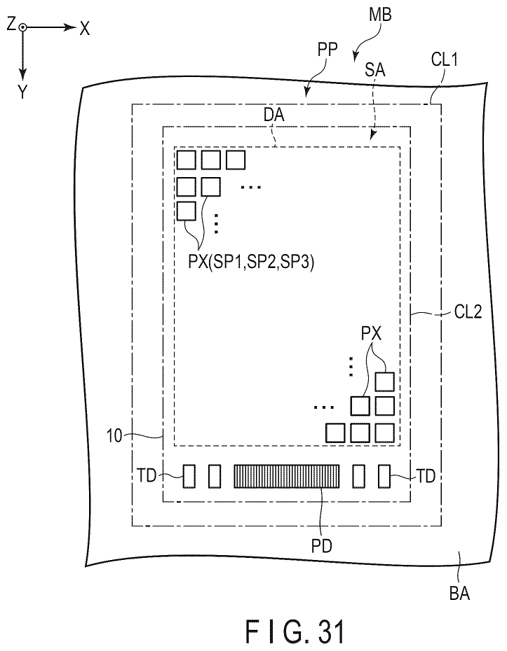

FIG. 31 is a plan view schematically showing the mother board MB according to this embodiment. In this embodiment, the display area DA is a rectangular shape elongated in the second direction Y. Further, the inspection pads TD are arranged in the vicinity (peripheral area SA) of the pads PD. Specifically, the inspection pads TD are placed between the cut line CL2 and the display area DA. It should be noted that the arrangement of the inspection pads TD is not limited to that of the example shown in FIG. 31. For example, the inspection pads TD each may as well disposed between each adjacent pair of pads PD.

By cutting along the cut line CL2, a display panel of the display device DSP comprising inspection pads TD can be formed. Even if the panel portion PP has such a configuration, advantageous effects similar to those of the first embodiment can be obtained by applying the configuration disclosed in the first embodiment thereto.

Note that the configuration of the panel portion PP may be applied in various other forms. For example, the display area DA of each panel portion PP may as well be a rectangle elongated in the first direction X, or may be a square. Further, the display area DA may be of such a shape including a plurality of linear portions or curved portions.

Based on the display devices, the mother boards and the manufacturing methods described above as embodiments of the invention, a person having ordinary skill in the art may achieve display devices, mother boards and manufacturing devices with arbitral design changes; however, as long as they fall within the scope and spirit of the present invention, all of such display devices are encompassed by the scope of the present invention.

A skilled person would conceive various changes and modifications of the present invention within the scope of the technical concept of the invention, and naturally, such changes and modifications are encompassed by the scope of the present invention. For example, if a skilled person adds/deletes/alters a structural element or design to/from/in the above-described embodiments, or adds/deletes/alters a step or a condition to/from/in the above-described embodiment, as long as they fall within the scope and spirit of the present invention, such addition, deletion, and altercation are encompassed by the scope of the present invention.

Furthermore, regarding the present embodiments, any advantage and effect those will be obvious from the description of the specification or arbitrarily conceived by a skilled person are naturally considered achievable by the present invention.

What is claimed is:

1. A mother board for a display device, comprising:
a plurality of panel portions each including a display area and a peripheral area surrounding the display area;
display elements disposed in the display area;
a rib layer disposed in the display area and the peripheral area and comprising pixel apertures respectively overlapping the display elements; and
inspection pads disposed on the peripheral area,
wherein
the inspection pads each includes:
a first metal layer; and
a second metal layer overlapping the first metal layer,
the rib layer is disposed between the first metal layer and the second metal layer, and includes a first aperture in which the second metal layer is brought into contact with the first metal layer,
the first metal layer includes:
a first layer formed of a first metal material;
a second layer formed of a second metal material and overlapping the first layer; and
a third layer formed of the first metal material and overlapping the second layer, and
the third layer includes an area exposing the second layer in the first aperture,
the second metal layer includes a first contact portion in contact with the second layer in the area, and
a second contact portion in contact with the third layer.

2. The mother board of claim 1, further comprising:
an inspection wiring line overlying the first metal layer, wherein
the first contact portion is located above the inspection wiring line, and
the second contact portion is not located above the inspection wiring line.

3. The mother board of claim 1, further comprising:
an organic insulating layer disposed between the first metal layer and the rib layer, wherein
the organic insulating layer includes a second aperture overlapping the first aperture,
an area of the second aperture, in plan view, is smaller than an area of the first aperture, and
the first contact portion and the second contact portion are located on an inner side the second aperture.

4. The mother board of claim 3, further comprising:
an inorganic insulating layer disposed between the organic insulating layer and the rib layer, wherein
the inorganic insulating layer includes a third aperture overlapping the first aperture and the second aperture.

5. The mother board of claim 1, further comprising:
a partition surrounding the pixel apertures in the display area, wherein
the partition includes a lower portion disposed above the rib layer and an upper portion including an end portion protruding from a side surface of the lower portion.

6. The mother board of claim 1, further comprising:
a sealing layer formed of an inorganic material and disposed above the rib layer, in the display area and the peripheral area, wherein
the sealing layer includes a fourth aperture overlapping the first aperture,
an area of the fourth aperture, in plan view, is smaller than an area of the first aperture.

7. A mother board for display device, comprising:
a plurality of panel portions each including a display area and a peripheral area surrounding the display area;
display elements disposed in the display area;
a rib layer disposed in the display area and the peripheral area and including pixel apertures overlapping the display elements; and
inspection pads disposed in the peripheral area, wherein
the inspection pads each include:
a first metal layer; and
a second metal layer overlapping the first metal layer,
the rib layer is disposed between the first metal layer and the second metal layer, and includes a first aperture in which the second metal layer is brought into contact with the first metal layer,
the first metal layer includes:
a first layer formed of a first metal material;
a second layer formed of a second metal material and overlapping the first layer; and
a third layer formed of the first metal material and overlapping the second layer,
the second metal layer includes:
a fourth layer formed of the first metal material,
a fifth layer formed of the second metal material and overlapping the fourth layer,
a sixth layer formed of the first metal material and overlapping the fifth layer, and
the inspection pads each comprise:
a first portion in which the first layer, the second layer, the fourth layer, the fifth layer, and the sixth layer are stacked, and
a second portion in which the first layer, the second layer, the third layer, the fourth layer, the fifth layer, and the sixth layer are stacked.

8. The mother board of claim 7, wherein
a thickness of the second portion is greater than a thickness of the first portion.

9. The mother board of claim 7, wherein
an interval between the second layer and the fifth layer in the second portion is greater than an interval between the second layer and the fifth layer in the first portion.

10. The mother board of claim 1, further comprising:
a cut line for separating the inspection pads from the peripheral area.

11. A display device comprising:
a display area;
a peripheral area surrounding the display area;
display elements disposed in the display area;
a rib layer disposed in the display area and the peripheral area and including pixel apertures overlapping the display elements; and
inspection pads disposed in the peripheral area, wherein
the inspection pads each include:
a first metal layer, and
a second metal layer overlapping the first metal layer,
the rib layer is disposed between the first metal layer and the second metal layer, and includes a first aperture in which the second metal layer is brought into contact with the first metal layer, the first metal layer comprises:
a first layer formed of a first metal material;
a second layer formed of a second metal material and overlapping the first layer; and
a third layer formed of the first metal material and overlapping the second layer,
the third layer includes an area exposing the second layer in the first aperture, and
the second metal layer includes
a first contact portion in contact with the second layer in the area, and
a second contact portion in contact with the third layer.

12. The display device of claim 11, further comprising:
an inspection wiring line overlying the first metal layer,
wherein
the first contact portion is located above the inspection wiring line, and
the second contact portion is not located above the inspection wiring line.
